(19) United States
(12) Patent Application Publication
(10) Pub. No.: US 2024/0143869 A1
(43) Pub. Date: May 2, 2024

(54) SYSTEM AND METHOD FOR USING SECTION GROUPING TO GENERATE SIMULATIONS

(71) Applicant: Figma, Inc., San Francisco, CA (US)

(72) Inventors: Nikolas Klein, San Francisco, CA (US); Ricky Rajani, San Francisco, CA (US); Sakura Rapolu, San Francisco, CA (US); Joel Miller, San Francisco, CA (US); Mihika Kapoor, San Francisco, CA (US); Kee Yen Yeo, San Francisco, CA (US); Sho Kuwamoto, San Francisco, CA (US)

(21) Appl. No.: 18/382,999

(22) Filed: Oct. 23, 2023

Related U.S. Application Data
(60) Provisional application No. 63/418,953, filed on Oct. 24, 2022.

(51) Int. Cl. G06F 30/20; G06F 30/12

(52) U.S. Cl. CPC G06F 30/20; G06F 30/12

(57) ABSTRACT

A computer system enables users to specify a plurality of cards that comprise a design interface or presentation, each card being renderable in a simulation or production environment, separate from other cards of the plurality of cards. The user can specify one or more sections or groupings of cards, where each section or grouping includes multiple cards. The user can specify multiple flow connections, including at least a first flow connection from one of the plurality of cards to a first section, where the cards of the first flow connection are not part of the first section. During a simulation rendering of the design interface, individual cards are rendered in a sequence that is based at least in part on one or more of the flow connections, including at least the first flow connection.

### RELATED APPLICATIONS

This application claims benefit of priority to Provisional Application No. 63/418,953, filed Oct. 24, 2022; the aforementioned priority application being hereby incorporated by reference in its entirety.

### TECHNICAL FIELD

Examples described herein relate to interactive graphic design systems, and more specifically, to a system and method for using section grouping to generate simulations.

### BACKGROUND

Software design tools have many forms and applications. In the realm of application user interfaces, for example, software design tools require designers to blend functional aspects of a program with aesthetics and even legal requirements, resulting in a collection of pages which form the user interface of an application. For a given application, designers often have many objectives and requirements that are difficult to track. To facilitate designers, some design tools enable production-environment simulations of cards (or other arrangements of design elements). For example, production-environment simulations can be implemented by rendering a sequence of cards in a manner that reflects state changes that can occur in the production environment. The use of such simulations enable designers to view how a design interface is implemented in a production environment, to enable designers to develop the design interface with the production environment in mind.

### BRIEF DESCRIPTION OF THE DRAWINGS

FIG. 1A illustrates an interactive graphic design system for a computing device of a user, according to one or more examples.

FIG. 1B illustrates a network computing system to implement an interactive graphic design system on a user computing device, according to one or more examples.

FIG. 1C illustrates a network computing system to implement an interactive graphic design system for multiple users in a collaborative network platform, according to one or more examples.

FIG. 2 illustrates components of a simulation engine for utilizing section groupings, according to one or more embodiments.

FIG. 3A illustrates an example method for implementing logic to provide section groupings (or sections) in an integrated graphic design system (IGDS), according to one or more embodiments.

FIG. 3B illustrates an example method for generating production-environment renderings for simulation, where the conditional sequencing of individual cards is based at least in part on state information associated with sections, according to one or more embodiments.

FIG. 4A illustrates a design interface on which a collection of cards is sectioned, according to one or more embodiments.

FIG. 4B through FIG. 4F illustrate a sequence of renderings, generated in a simulation environment, for a collection of sectioned cards, according to one or more embodiments.

FIG. 5 illustrates a network computer system on which one or more embodiments can be implemented.

FIG. 6 illustrates a user computing device for use with one or more examples, as described.

### DETAILED DESCRIPTION

In embodiments, an integrated graphic design system (IGDS) enables users to create sections, which are logical elements that represent a grouping of multiple cards. Cards can correspond to frames which include design elements, renderable in production to display a screen, presentation (e.g., slide) or page. In embodiments, the sections can be specified as targets for flow connections, in connection with cards of a design being rendered in a simulation environment. Sections can also be associated with state information that can identify, for example, which cards of a respective section were most recently rendered. The IGDS can use sections, as well as state information associated with sections, to determine a sequence in which cards of a design or presentation are rendered.

Still further, embodiments provide a network computer system that enables one or more users to create cards for a design interface or presentation, where each of the plurality of cards is renderable in a simulation or production environment separate from other cards of the plurality of cards. The network computer system enables user(s) to specify one or more sections (alternatively referenced as section groupings) of cards from the plurality of groupings, where each of the sections include multiple cards. The user can further specify multiple flow connections, including at least a first flow connection from one of the plurality of cards to a first section of the one or more sections. During a simulation rendering of the design interface or presentation, the system renders cards of the plurality of cards in a sequence that is based at least in part on one or more of the flow connections, including at least the first flow connection.

In examples, flow connections that specify a section (or section grouping) as a target can cause the computer system to select which card of the section is to be rendered at a particular moment during the simulation. The computer system can select which card of the section to render for the simulation based on state information that has been recorded during the simulation with regards to the section. In examples, the state information can identify the card that was most previously rendered. Thus, in examples, when a card from a section is rendering during a simulation rendering, the card can reflect or correspond to the card of the section that was most recently rendered during the simulation.

One or more embodiments described herein provide that methods, techniques, and actions performed by a computing device are performed programmatically, or as a computer-implemented method. Programmatically, as used herein, means through the use of code or computer-executable instructions. These instructions can be stored in one or more memory resources of the computing device. A programmatically performed step may or may not be automatic.

One or more embodiments described herein can be implemented using programmatic modules, engines, or components. A programmatic module, engine, or component can include a program, a sub-routine, a portion of a program, or a software component or a hardware component capable of performing one or more stated tasks or functions. As used herein, a module or component can exist on a hardware component independently of other modules or components. Alternatively, a module or component can be a shared element or process of other modules, programs or machines.

Some embodiments described herein can generally require the use of computing devices, including processing and memory resources. For example, one or more embodiments described herein may be implemented, in whole or in part, on computing devices such as servers, desktop computers, cellular or smartphones, tablets, wearable electronic devices, laptop computers, printers, digital picture frames, network equipment (e.g., routers) and tablet devices. Memory, processing, and network resources may all be used in connection with the establishment, use, or performance of any embodiment described herein (including with the performance of any method or with the implementation of any system).

Furthermore, one or more embodiments described herein may be implemented through the use of instructions that are executable by one or more processors. These instructions may be carried on a computer-readable medium. Machines shown or described with figures below provide examples of processing resources and computer-readable mediums on which instructions for implementing embodiments of the invention can be carried and/or executed. In particular, the numerous machines shown with embodiments of the invention include processor(s) and various forms of memory for holding data and instructions. Examples of computer-readable mediums include permanent memory storage devices, such as hard drives on personal computers or servers. Other examples of computer storage mediums include portable storage units, such as CD or DVD units, flash memory (such as carried on smartphones, multifunctional devices or tablets), and magnetic memory. Computers, terminals, network enabled devices (e.g., mobile devices, such as cell phones) are all examples of machines and devices that utilize processors, memory, and instructions stored on computer-readable mediums. Additionally, embodiments may be implemented in the form of computer-programs, or a computer usable carrier medium capable of carrying such a program.

System Description

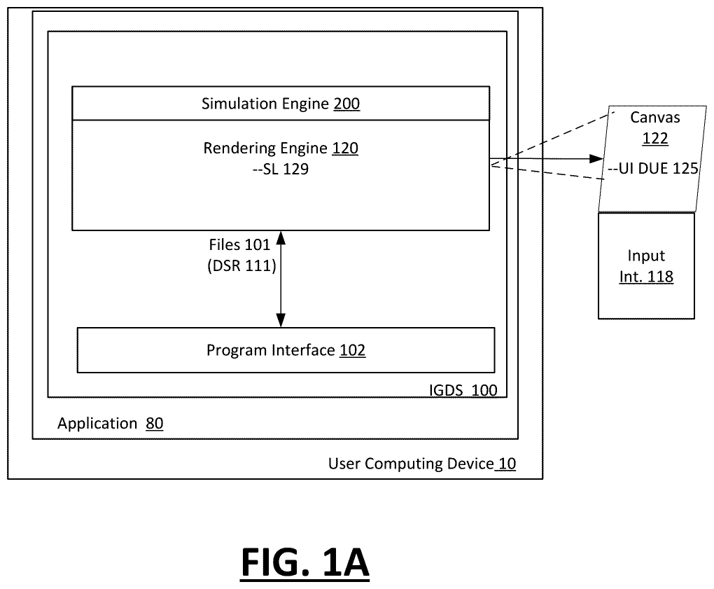

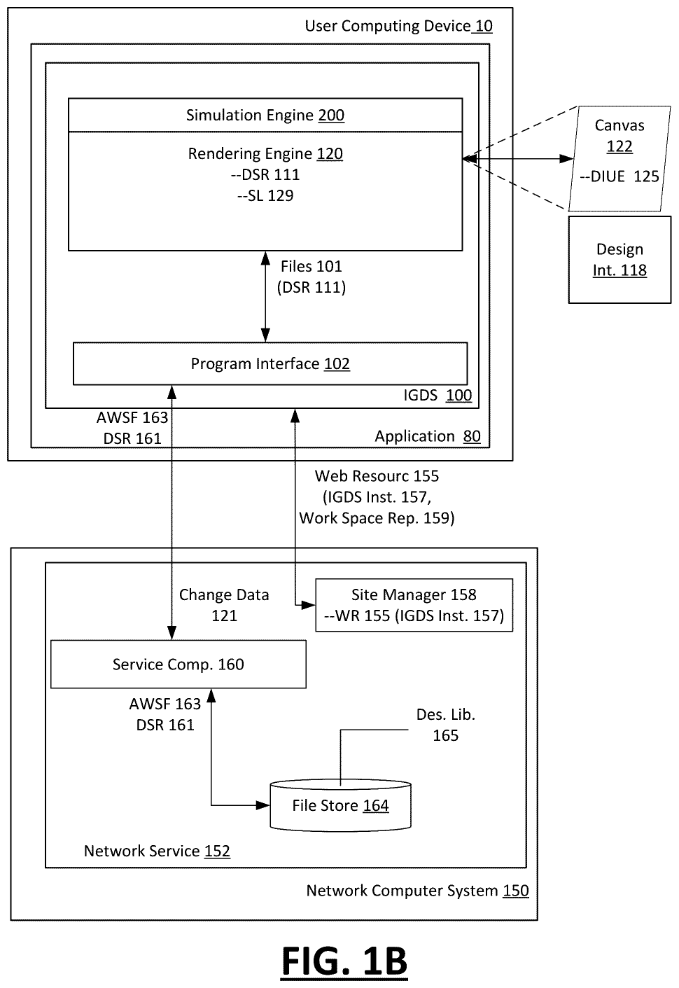

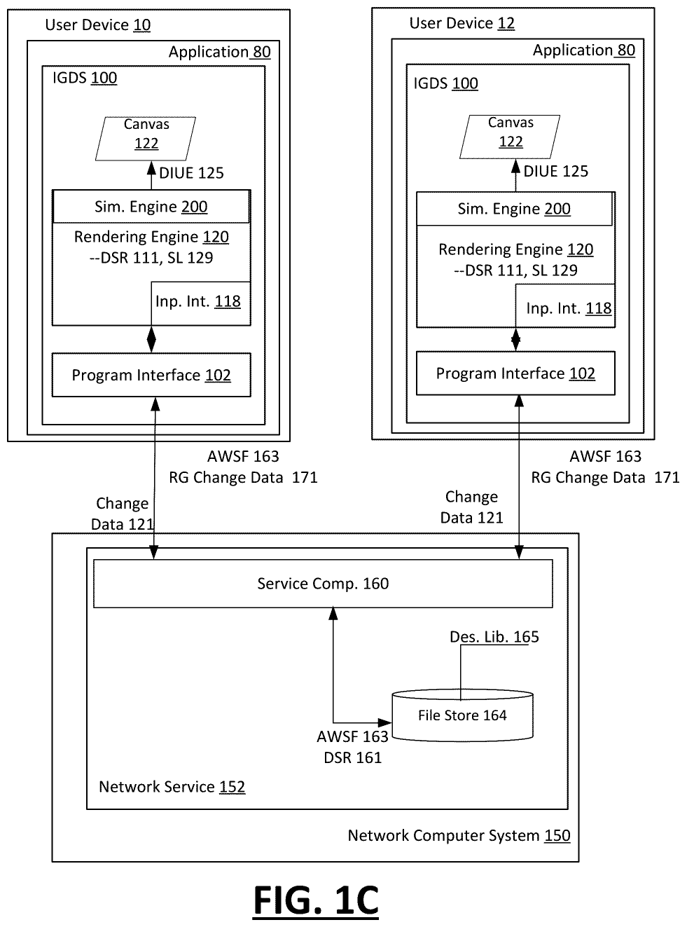

FIG. 1A illustrates an interactive graphic design system for a computing device of a user, according to one or more examples. An interactive graphic design system (“IGDS”) 100 can be implemented in any one of multiple different computing environments. For example, in some variations, the IGDS 100 can be implemented as a client-side application that executes on the user computing device 10 to provide functionality as described with various examples. In other examples, such as described below, the IGDS 100 can be implemented through use of a web-based application 80. As an addition or alternative, the IGDS 100 can be implemented as a distributed system, such that processes described with various examples execute on a network computer (e.g., server) and on the user device 10.

According to examples, the IGDS 100 can be implemented on a user computing device 10 to enable a corresponding user to design various types of interfaces using graphical elements. The IGDS 100 can include processes that execute as or through a web-based application 80 that is installed on the computing device 10. As described by various examples, web-based application 80 can execute scripts, code and/or other logic (the “programmatic components”) to implement functionality of the IGDS 100. Additionally, in some variations, the IGDS 100 can be implemented as part of a network service, where web-based application 80 communicates with one or more remote computers (e.g., server used for a network service) to executes processes of the IGDS 100.

In some examples, web-based application 80 retrieves some or all of the programmatic resources for implementing the IGDS 100 from a network site. As an addition or alternative, web-based application 80 can retrieve some or all of the programmatic resources from a local source (e.g., local memory residing with the computing device 10). The web-based application 80 may also access various types of data sets in providing the IGDS 100. The data sets can correspond to files and libraries, which can be stored remotely (e.g., on a server, in association with an account) or locally.

In examples, the web-based application 80 can correspond to a commercially available browser, such as GOOGLE CHROME (developed by GOOGLE, INC.), SAFARI (developed by APPLE, INC.), and INTERNET EXPLORER (developed by the MICROSOFT CORPORATION). In such examples, the processes of the IGDS 100 can be implemented as scripts and/or other embedded code which web-based application 80 downloads from a network site. For example, the web-based application 80 can execute code that is embedded within a webpage to implement processes of the IGDS 100. The web-based application 80 can also execute the scripts to retrieve other scripts and programmatic resources (e.g., libraries) from the network site and/or other local or remote locations. By way of example, the web-based application 80 may execute JAVASCRIPT embedded in an HTML resource (e.g., web-page structured in accordance with HTML 5.0 or other versions, as provided under standards published by W3C or WHATWG consortiums). In some examples, the rendering engine 120 and/or other components may utilize graphics processing unit (GPU) accelerated logic, such as provided through WebGL (Web Graphics Library) programs which execute Graphics Library Shader Language (GLSL) programs that execute on GPUs.

According to examples, user of computing device 10 operates web-based application 80 to access a network site, where programmatic resources are retrieved and executed to implement the IGDS 100. In this way, the user may initiate a session to implement the IGDS 100 for purpose of creating and/or editing a design interface. In examples, the IGDS 100 includes a program interface 102, an input interface 118, and a rendering engine 120. The program interface 102 can include one or more processes which execute to access and retrieve programmatic resources from local and/or remote sources.

In an implementation, the program interface 102 can generate, for example, a canvas 122, using programmatic resources which are associated with web-based application 80 (e.g., HTML 5.0 canvas). As an addition or variation, the program interface 102 can trigger or otherwise cause the canvas 122 to be generated using programmatic resources and data sets (e.g., canvas parameters) which are retrieved from local (e.g., memory) or remote sources (e.g., from network service).

The program interface 102 may also retrieve programmatic resources that include an application framework for use with canvas 122. The application framework can include data sets which define or configure, for example, a set of interactive graphic tools that integrate with the canvas 122 and which comprise the input interface 118, to enable the user to provide input for creating and/or editing a design interface.

According to some examples, the input interface 118 can be implemented as a functional layer that is integrated with the canvas 122 to detect and interpret user input. The input interface 118 can, for example, use a reference of the canvas 122 to identify a screen location of a user input (e.g., ‘click’). Additionally, the input interface 118 can interpret an input action of the user based on the location of the detected input (e.g., whether the position of the input indicates selection of a tool, an object rendered on the canvas, or region of the canvas), the frequency of the detected input in a given time period (e.g., double-click), and/or the start and end position of an input or series of inputs (e.g., start and end position of a click and drag), as well as various other input types which the user can specify (e.g., right-click, screen-tap, etc.) through one or more input devices. In this manner, the input interface 118 can interpret, for example, a series of inputs as a design tool selection (e.g., shape selection based on location of input), as well as inputs to define attributes (e.g., dimensions) of a selected shape.

Additionally, the program interface 102 can be used to retrieve, from local or remote sources, programmatic resources and data sets which include files 101 which comprise an active workspace for the user. In examples, the files 101 can include a collection of cards, where the cards of the collection provide the design elements for a user interface or presentation when rendered in a production-environment. In examples, the individual cards can represent, for example, an application screen or a state of an application. When rendered in production or through simulation, cards can be rendered sequentially or in series, such that one card replaces another card. The retrieved data sets can include one or more cards that include design elements which collectively form a design interface, or a design interface that is in progress. Each file 101 can include one or multiple data structure representations 111 (shown as “DSR 111”) which collectively define the design interface. As described in more detail with some examples, the data structure representations 111 can be in the form of a document object model (DOM). The files 101 may also include additional data sets which are associated with the active workspace. For example, as described with some examples, the workspace file can store animation data sets which define animation behavior as between objects or states in renderings of the canvas 122.

In examples, the rendering engine 120 uses the DOM representations 111 to render a corresponding design 125 (or presentation) on the canvas 122, wherein the design reflects graphic elements and their respective attributes as provided with the individual pages of the files 101. The user can edit the design using the input interface 118. Alternatively, the rendering engine 120 can generate a blank page for the canvas 122, and the user can use the input interface 118 to generate the design. As rendered, the design can include graphic elements such as a background and/or a set of objects (e.g., shapes, text, images, programmatic elements), as well as attributes of the individual graphic elements. Each attribute of a graphic element can include an attribute type and an attribute value. For an object, the types of attributes include, shape, dimension (or size), layer, type, color, line thickness, text size, text color, font, and/or other visual characteristics. Depending on implementation, the attributes reflect properties of two- or three-dimensional designs. In this way, attribute values of individual objects can define, for example, visual characteristics of size, color, positioning, layering, and content, for elements that are rendered as part of the design.

Network Computing System to Implement IGDS

FIG. 1B illustrates a network computing system to implement an interactive graphic design system on a user computing device, according to one or more examples. A network computing system such as described with an example of FIG. 1B can be implemented using one or more servers which communicate with user computing devices over one or more networks.

In an example of FIG. 1B, the network computing system 150 perform operations to enable the IGDS 100 to be implemented on the user computing device 10. In variations, the network computing system 150 provides a network service 152 to support the use of the IGDS 100 by user computing devices that utilize browsers or other web-based applications. The network computing system 150 can include a site manager 158 to manage a website where a set of web-resources 155 (e.g., web page) are made available for site visitors. The web-resources 155 can include instructions, such as scripts or other logic (“IGDS instructions 157”), which are executable by browsers or web components of user computing devices.

In some variations, once the computing device 10 accesses and downloads the web-resources 155, web-based application 80 executes the IGDS instructions 157 to implement functionality such as described with some examples of FIG. 1A. For example, the IGDS instructions 157 can be executed by web-based application 80 to initiate the program interface 102 on the user computing device 10. The initiation of the program interface 102 may coincide with the establishment of, for example, a web-socket connection between the program interface 102 and a service component 160 of the network computing system 150.

In some examples, the web-resources 155 includes logic which web-based application 80 executes to initiate one or more processes of the program interface 102, causing the IGDS 100 to retrieve additional programmatic resources and data sets for implementing functionality as described by examples. The web resources 155 can, for example, embed logic (e.g., JAVASCRIPT code), including GPU accelerated logic, in an HTLM page for download by computing devices of users. The program interface 102 can be triggered to retrieve additional programmatic resources and data sets from, for example, the network service 152, and/or from local resources of the computing device 10, in order to implement the IGDS 100. For example, some of the components of the IGDS 100 can be implemented through web-pages that can be downloaded onto the computing device 10 after authentication is performed, and/or once the user performs additional actions (e.g., download one or more pages of the workspace associated with the account identifier). Accordingly, in examples as described, the network computing system 150 can communicate the IGDS instructions 157 to the computing device 10 through a combination of network communications, including through downloading activity of web-based application 80, where the IGDS instructions 157 are received and executed by web-based application 80.

The computing device 10 can use web-based application 80 to access a website of the network service 152 to download the webpage or web resource. Upon accessing the website, web-based application 80 can automatically (e.g., through saved credentials) or through manual input, communicate an account identifier to the service component 160. In some examples, web-based application 80 can also communicate one or more additional identifiers that correlate to a user identifier.

Additionally, in some examples, the service component 160 can use the user or account identifier of the user identifier to retrieve profile information from a user profile store. As an addition or variation, profile information for the user can be determined and stored locally on the user's computing device 10.

The service component 160 can also retrieve the files of an active workspace (“active workspace files 163”) that are linked to the user account or identifier from a file store 164. The profile store can also identify the workspace that is identified with the account and/or user, and the file store 164 can store the data sets that comprise the workspace. The data sets stored with the file store 164 can include, for example, the pages of a workspace, data sets that identify constraints for an active set of workspace files, and one or more data structure representations 161 for the design under edit which is renderable from the respective active workspace files.

Additionally, in examples, the service component 160 provides a representation 159 of the workspace associated with the user to the web-based application 80, where the representation identifies, for examples, individual files associated with the user and/or user account. The workspace representation 159 can also identify a set of files, where each file includes one or multiple pages, and each page including objects that are part of a design interface.

On the user device 10, the user can view the workspace representation through web-based application 80, and the user can elect to open a file of the workspace through web-based application 80. In examples, upon the user electing to open one of the active workspace files 163, web-based application 80 initiates the canvas 122. For example, the IGDS 100 can initiate an HTML 5.0 canvas as a component of web-based application 80, and the rendering engine 120 can access one or more data structures representations 111 of a design interface under edit, to render the corresponding design on the canvas 122.

The service component 160 may also determine, based on the user credentials, a permission setting or role of the user in connection with the account identifier. The permission settings or role of the user can determine, for example, the files which can be accessed by the user. In some examples, the implementation of the rendering engine 120 on the computing device 10 can be configured based at least in part on the role or setting of the user. For example, the user's ability to specify constraints for the design can be determined by the user's permission settings, where the user can be enabled or precluded from creating constraints 145 for the design based on their respective permission settings. Still further, in some variations, the response action which the user can take to resolve a conflict can be limited by the permission setting of the user. For example, the ability of the user to ignore constraints 145 can be based on the permission setting of the user.

In examples, the changes implemented by the rendering engine 120 to the design can also be recorded with the respective DOM representations 111, as stored on the computing device 10. The program interface 102 can repeatedly, or continuously stream change data 121 to the service component 160, wherein the updates reflect edits as they are made to the design 125. The service component 160 can receive the change data 121, which in turn can be used to implement changes to the network-side data structure representations 161. In this way, the network-side data structure representations 161 for the active workspace files 163 can mirror (or be synchronized with) the local DOM representations 111 on the user computing device 10. When the rendering engine 120 implements changes to the design on the user device 10, the changes can be recorded or otherwise implemented with the local DOM representations 111, and the program interface 102 can stream the changes as change data 121 to the service component 160 in order to synchronize the local and network-side representations 111, 161 of the design. This process can be performed repeatedly or continuously, so that the local and network-side representations 111, 161 of the design remain synchronized.

Collaborative Network Platform

FIG. 1C illustrates a network computing system to implement an interactive graphic design system for multiple users in a collaborative network platform, according to one or more examples. In an example of FIG. 1C, a collaborative network platform is implemented by the network computing system 150, which communicates with multiple user computing devices 10, 12 over one or more networks (e.g., World Wide Web) to implement the IGDS 100 on each computing device. While FIG. 1C illustrates an example in which two users utilize the collaborative network platform, examples as described allow for the network computing system 150 to enable collaboration on design interfaces amongst a larger group of users.

With respect to FIG. 1C, the user computing devices 10, 12 can be assumed as being operated by users that are associated with a common account, with each user computing device 10, 12 implementing a corresponding IGDS 100 to access the same workspace during respective sessions that overlap with one another. Accordingly, each of the user computing devices 10, 12 may access the same set of active workspace files 163 at the same time, with the respective program interface 102 of the IGDS 100 on each user computing device 10, 12 operating to establish a corresponding communication channel (e.g., web socket connection) with the service component 160.

In examples, the service component 160 can communicate a copy of the active workspace files 163 to each user computing device 10, 12, such that the computing devices 10, 12 render the design of the active workspace files 163 at the same time. Additionally, each of the computing devices 10, 12 can maintain a local DOM representations 111 of the respective design, as determined from the active workspace files 163. The service component 160 can also maintain a network-side data structure representation 161 obtained from the files of the active workspace 163, and coinciding with the local DOM representations 111 on each of the computing devices 10, 12.

The network computing system 150 can continuously synchronize the active workspace files 163 on each of the user computing devices. In particular, changes made by users to the design on one computing device 10, 12 may be immediately reflected on the design rendered on the other user computing device 10, 12. By way of example, the user of computing devices 10 can make a change to the respective design, and the respective rendering engine 120 can implement an update that is reflected in the local copy of the DOM representations 111. From the computing device 10, the program interface 102 of the IGDS 100 can stream change data 121, reflecting the change of the user input, to the service component 160. The service component 160 processes the change data 121 of the user computing device. The service component 160 can use the change data 121 to make a corresponding change to the network-side data structure representation 161. The service component 160 can also stream remotely-generated change data 171 (which in the example provided, corresponds or reflects change data 121 received from the user device 10) to the computing device 12, to cause the corresponding IGDS 100 to update the design as rendered on that device. The computing device 12 may also use the remotely generated change data 171 to update with the local DOM representations 111 of that computing device 12. The program interface 102 of the computing device 12 can receive the update from the network computing system 150, and the rendering engine 120 can update the design and the respective local DOM representations 111 of the computing device 12.

The reverse process can also be implemented to update the data structure representations 161 of the network computing system 150 using change data 121 communicated from the second computing device 12 (e.g., corresponding to the user of the second computing device updating the design as rendered on the second computing device 12). In turn, the network computing system 150 can stream remotely generated change data 171 (which in the example provided, corresponds or reflects change data 121 received from the user device 12) to update the local DOM representations 111 of the design on the first computing device 10. In this way, the design of the first computing device 10 can be updated as a response to the user of the second computing device 12 providing user input to change the design.

To facilitate the synchronization of the DOM representations 111, 111 on the computing devices 10, 12, the network computing system 150 may implement a stream connector to merge the data streams which are exchanged between the first computing device 10 and the network computing system 150, and between the second computing device 12 and the network computing system 150. In some implementations, the stream connector can be implemented to enable each computing device 10, 12 to make changes to the network-side data representation 161, without added data replication that may otherwise be required to process the streams from each device separately.

Additionally, over time, one or both of the computing devices 10, 12 may become out-of-sync with the server-side data representation 161. In such cases, the respective computing device 10, 12 can redownload the active workspace files 163, to restart the maintenance of the data structure representation of the design that is rendered and edited on that device.

With reference to FIG. 1A through FIG. 1C, in examples, the IGDS 100 can implement a simulation engine 200 for users. The IGDS 100 can implement alternative modes, including a design mode and a simulation mode. In the simulation mode, the simulation engine 200 generates simulation renderings for individual cards of a collection. The simulation engine 200 can render a sequence of cards in order to provide users with a production-environment simulation of a design interface or presentation that is in progress or under edit. In examples, the simulation engine 200 can be implemented as part of the rendering engine 120. In variations, the simulation engine 200 can be implemented through another component.

In design mode, the IGDS 100 can include section logic 129 to enable user(s) to specify one or more sections for each design 125. Each section can identify a set of cards. When a section is created, the DOM representation 111 of the design 125 can include an additional root node that represents the section, and nodes representing individual cards that are selected for the section can become sub-nodes to the root node. As described, the sectioning of the design can include additional logic that is implemented specifically or automatically for the section. A similarity search of a design element can, for example, be performed to determine another design element of a section which resembles a selected design element. Further, the user can provide additional input to create or incorporate additional design elements based on such section-level similarity searches.

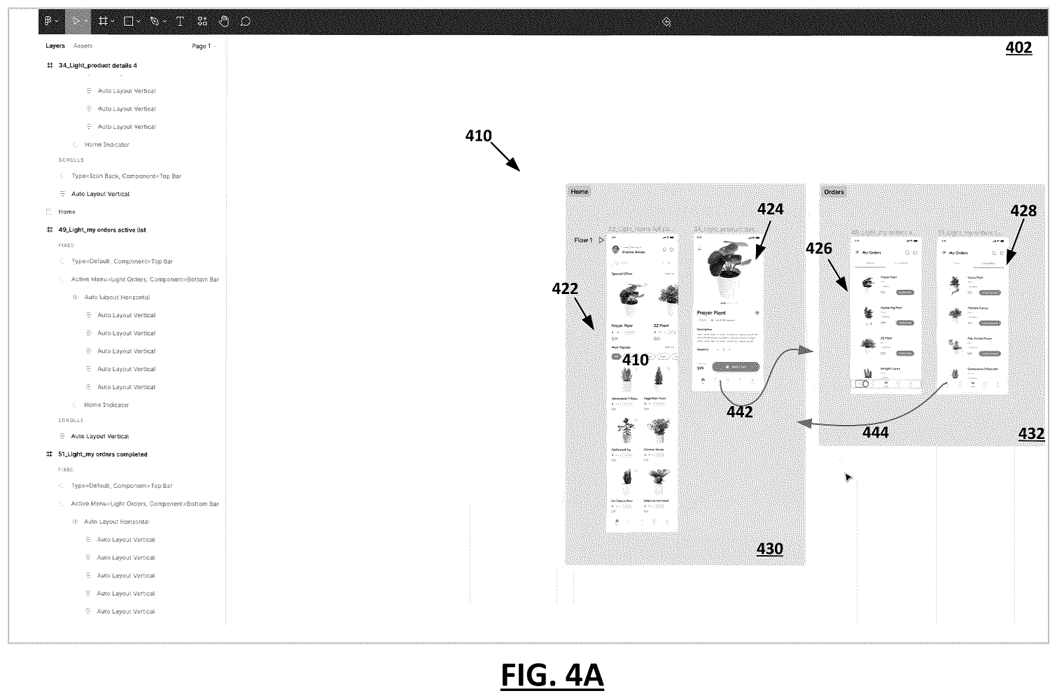

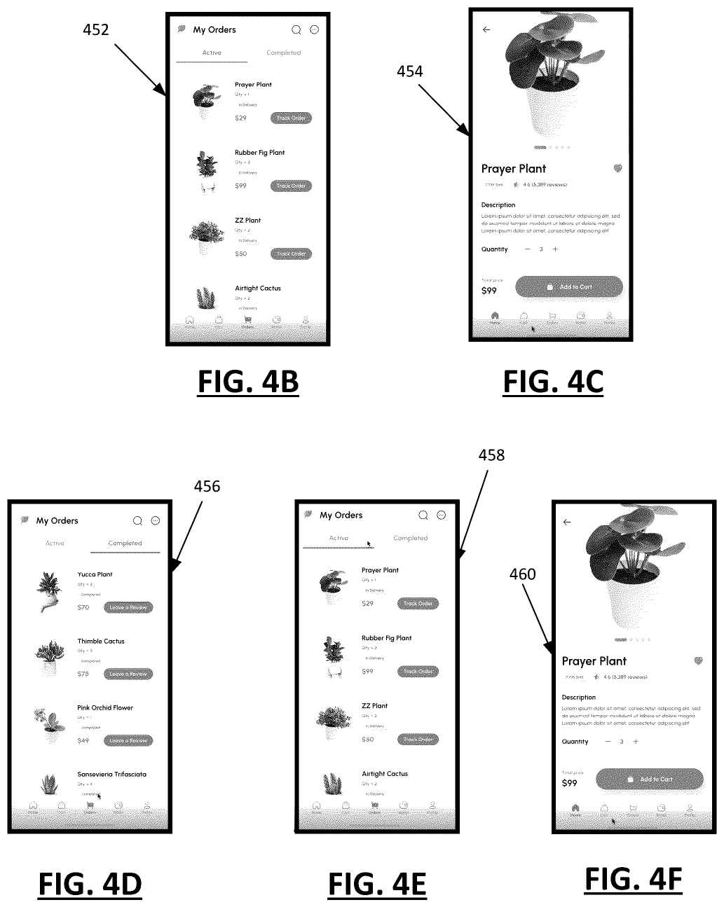

Users can also specify flow information that are specific to sections, rather than cards or design elements of cards. For example, as shown in FIG. 4A, flow information can be represented by line connectors which can terminate at sections, signifying that one of the cards of a section are to be rendered following an event identified by the source of the line connector.

The IGDS 100 can further implement the section logic 129 to maintain state information for each identified section. The IGDS 100 can implement the section logic 129 to maintain the state information when sections are rendered during the simulation renderings of the design 125. The state information can contribute to the determination of the sequence in which cards are rendered during the simulation.

Simulation Engine

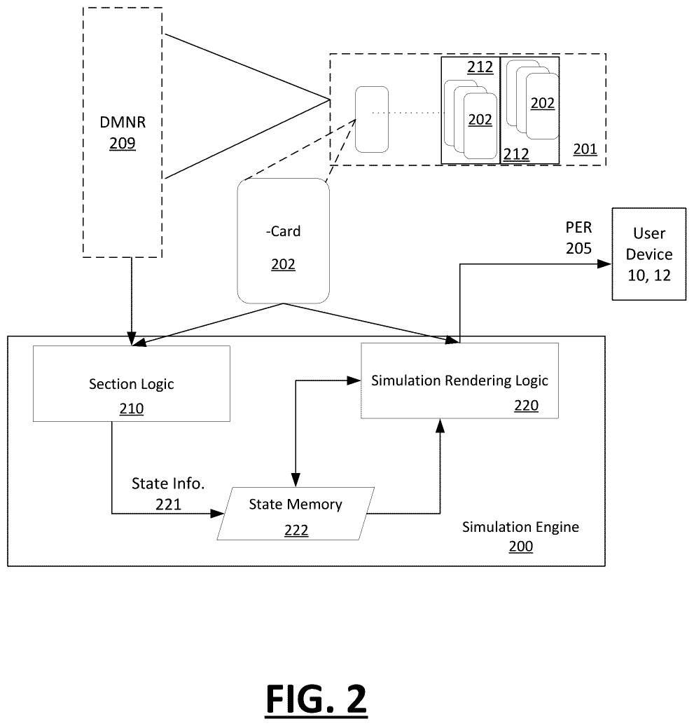

FIG. 2 illustrates a simulation engine for utilizing section groupings, in accordance with one or more embodiments. The simulation engine 200 can be implemented or otherwise provided with the IGDS 100 in order to enable users to simulate how a sequence of cards would be rendered in the production-environment (“production-environment rendering” or “simulation rendering”), where each card includes a top-level frame that contains a set of design elements. Accordingly, the simulation engine 200 can generate production-environment renderings as an output, often utilizing multiple cards 200 to of a collection 201, where design elements of each card 202 combine to simulate a set of production elements for a user interface or presentation in the production-environment.

In some examples, a simulation engine 200 can be implemented as part of the rendering engine 120 for the IGDS 100. For example, the IGDS 100 can implement alternative modes, including a design mode and a simulation mode, where in the simulation mode, the rendering engine 120 executes processes of simulation engine 200 to render production-environment renderings 205 as an output, where the production-environment renderings 205 simulate a design interface when it is in production. The production-environment renderings 205 can be provided to user devices 10, 12, to enable designs and users of the IGDS 100 to view how designs in progress may appear in the production environment. In variations, the simulation engine 200 can be implemented as a separate component or application.

In examples, the simulation engine 200 includes processes represented by section logic 210 and simulation rendering logic 220. When initiated, the simulation engine 200 generates a production-environment rendering 205 of a series of cards 202 that comprise a particular design 201 or presentation. During or in context of simulating production-environment renderings, the section logic 210 can execute to identify which cards 202 of the design or presentation to load, and simulation rendering logic 220 generates the production-environment for the rendering.

The simulation rendering logic 220 generates a production-environment rendering 205 from each card 202 that is processed by the simulation engine 200, where the production-environment rendering 205 includes production elements of a simulated user interface or presentation. Further, the production-environment renderings 205 can be interactive or dynamically responsive to events, such as responsive to user input that simulates an end user input in the production-environment.

In examples, the simulation renderings 205 can be sequenced, based at least in part on conditions specified with information associated with individual cards 202 (e.g., line connectors to indicate flow), as well as state information associated with each section. For example, line connectors (or flow connectors) may identify a sequence in which a given card is rendered, a condition specified by the line connector is detected (e.g., design element identified by line connector receives input), and a next card or section from which the next card is to be determined. Each time a card is rendered from one of the sections 212, the section logic 210 updates state information 221 recorded with a state memory 222. Further, the simulation rendering logic 220 can process flow information (e.g., line connections) associated with a rendered card 202, responsive to the simulation rendering logic 220 detecting an event (e.g., user interaction with design element of rendered card 202A). Based on the flow information, the simulation rendering logic 220 can identify a target for determining the next card of the flow or sequence. If the flow identifies, for example, another card, then the simulation rendering logic 220 renders the next card. If the flow identifies a section as the target of the flow information, then the simulation rendering logic 220 checks the state memory 222 for state information 221 for that section. If state information 221 is identified, then the simulation rendering logic 220 uses the state information to generate the rendering of the card identified from the state information 221 (e.g., the most recently rendered card of the section). If there is no state information for the identified section, a default sequence rule may be used to identify which card of the section should be rendered. Upon rendering each card, the section logic 210 again updates state information 221 recorded with the state memory 222.

Among other examples, examples such as described with FIG. 2 enable design users to specify simplified flow information for a design interface, where simulation renderings of a production-environment are more accurately reflect an end user's interaction with the production-environment.

Methodology

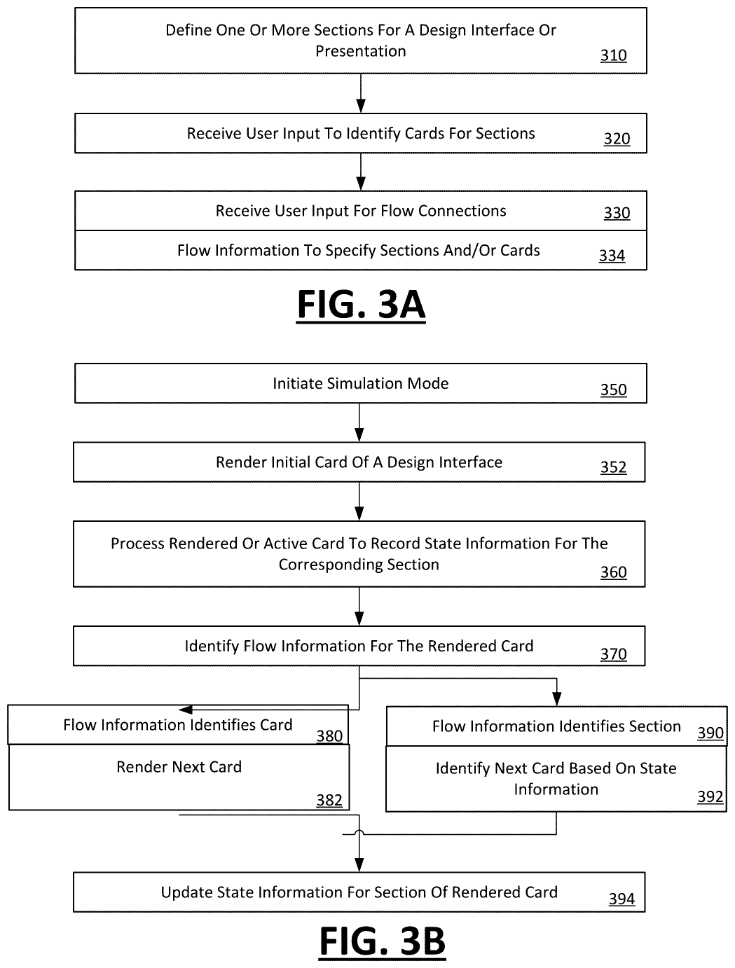

FIG. 3A illustrates an example method for implementing logic to provide section groupings (or sections) in an integrated graphic design system (IGDS), according to one or more embodiments. FIG. 3B illustrates an example method for generating production-environment renderings for simulation, where the conditional sequencing of individual cards is based at least in part on state information associated with sections, according to one or more embodiments. In describing examples of FIG. 3A and FIG. 3B, reference is made to elements of FIG. 1 and FIG. 2 for purpose of illustration.

With reference to FIG. 3A, in step 310, a user of the IGDS 100 defines one or more sections for a design interface or presentation. The IGDS 100 can be operated in a design mode to enable individual users, or users working in collaboration, to create and update a design or presentation. The design or presentation can include a collection of cards, where each card corresponds to, for example, application or presentation content for a display screen, window or page. The IGDS 100 can maintain a hierarchical nodal representation of a design or presentation on the canvas 122, where nodes are created as top level or root nodes to represent corresponding sections of the design interface or presentation. In examples, the IGDS 100 maintains a document object model (DOM) for a designed interface or presentation, where the DOM includes a hierarchical arrangement of nodes. Further, in some examples, a section can be defined as a root node (Level 0). Within each root node, sub-nodes can be arranged to have different sub-levels. In some examples, each card of the collection can be represented by the top-most sub-node (Level 1), and design elements that are parentless (i.e., design elements that are not nested within any other design element other than the container of the card) can be represented as a next highest sub-node (Level 2) to the topmost sub-node (e.g., the container). In turn, any child design element to one of the design elements represented by one of the parentless design elements can be represented by a third level sub-node (i.e., Level 3 node) and so forth.

In step 320, user input is received to identify the cards of a section. The input can be received over multiple durations. For example, a user can initially select multiple cards that are to comprise each of the one or more sections. As described with other examples, a section corresponds to a grouping of cards, where each card is a container that represents, for example, a production-environment screen (or a screen in a particular state) or a paginated presentation (e.g., such as a slide for a slide deck). For each of the one or more sections, the IGDS 100 enables the user to make a selection of cards for from, for example, a larger collection of cards that that form the designed interface or presentation. For example, a design user can select a section to encompass cards of a given module or workflow for an application (e.g., mobile app). In some implementations, the collection of cards for the designed interface or presentation can be rendered at one time on the canvas 122. The user can utilize tools or otherwise interact with the canvas to select one or more cards for grouping as a given section. As an addition or variation, the user can select, delete, or modify cards that comprise the section.

When the user selects cards for a section, the IGDS 100 can implement processes that update the DOM of the design or presentation. As described, each section can correspond to a root note in the DOM representation. In some implementations, the creation of the section can result in a new root node corresponding to the newly created section. Further, each card that is associated with the section can be hierarchically arranged under the section node in the DOM representation.

In step 330, the user specifies flow connections for the design interface or presentation. The flow connections can specify conditional flows which specify a sequence under which different cards of the designed interface or presentation are rendered in the production environment. In some examples, the flow connections are rendered as graphic elements on the canvas, such as in the form of a line with arrows or end segments to reflect, for example, a sequence or flow direction. The graphic elements can be rendered on the canvas when the IGDS 100 is in design mode. When simulation is implemented, the graphic elements representing the flow connections can be hidden (or not rendered), as the graphic elements do not form part of the production rendering.

With regard to each of the defined section(s), in step 334, the user can specify various types of flow information, including internal flow information that identify other cards of a common section, and external flow information that specify sections as targets of a flow. Collectively, the various flow connectors can specify conditions under which a given sequence of cards can be rendered in the production environment. As shown with examples of FIG. 4A through FIG. 4F, flow information can be specified as line connectors (or flow connectors) that specify a source or origin, and a target. In examples, the user can provide input for the flow information by specifying a section as a target. As further described, in such case, state information associated with the section determines which card of the section is to be rendered in a given sequence for that flow.

With reference to FIG. 3B, in step 350, production-environment renderings of the design interface or presentation can be initiated by the IGDS 100, operating in simulation mode. In step 352, simulation rendering logic 220 renders an initial card of a design or interface. In step 360, the section logic 210 and/or simulation rendering logic 220 processes information associated with the rendered or active card to record state information for the corresponding section. The state information can include, for example, (i) an identifier for the section that contains the card, (ii) flow connectors that define conditions for identifying a next card of the design interface or presentation that is to be rendered, and (iii) conditions for selecting which of multiple flow connectors are to be used in determining which of the cards of the design interface or presentation is to be rendered next by the simulation engine 200. In examples, the section logic 210 updates state information 221 stored with state memory 222 for the identified section, where the state information identifies which card of the section was most recently rendered.

In step 370, once the section logic 210 detects one or more events, the section logic 210 identifies flow information (e.g., line or flow connection) for the rendered card. In step 380, if the identified flow information identifies another card, then in step 382, the simulation rendering logic 220 renders the next card as part of the production-environment rendering. In step 390, if the flow information identifies a section, rather than a specific card, then in step 392, the rendering logic identifies which card of the identified section is next based on state information for the identified section. For example, the identified flow connector can specify a section identifier. If the identified flow connector identifies another section, then the section logic 210 looks up state information for the identified section from the state memory 212. The state information can identify the card of the section that was most recently rendered during the simulated rendering of the design interface or presentation, and the card identified by the state information can be rendered as the next card. In variations, the card identified by the state information is used to determine which card is the next card that is to be rendered.

In step 394, once the next card is rendered, the section logic 210 updates the state information for the particular section of the next card. The method repeats until the simulation engine terminates rendering of the cards.

### Examples

FIG. 4A illustrates a canvas 402 on which elements for a design interface 410 are rendered to enable design input and modification. An example of FIG. 4A can be implemented by one or more users operating the 100 in design mode. As shown, the design interface 410 includes multiple cards 422, 424, 426, 428, and the cards can be grouped into sections 430, 432. The grouping of cards 422, 424 as section 430, and cards 426, 428 as section 432 can be implemented by user input. For example, the user can draw a box around each set of cards 422, 424 and 426, 428 to designate each set of cards as respective section 430, 432.

In the design mode, the user can specify multiple flows defining the sequence in which individual cards 422, 424, 426, 428 of the design interface 410 are to be rendered in the production environment. The user can operate the IGDS 100 to specify flows using visual line connectors 442, 444. The line connectors 442, 444 can extend from card (source) to section (target), signifying a production environment sequence in which one of the cards of the target section is to be rendered in the production environment following rendering of the source card. Each line connector 442, 444 can indicate a condition or event relating to the source. For example, a line connector originating from a specific feature of the source card indicates that an event relating to the particular feature (e.g., user input received) will trigger the flow (or sequence of renderings) indicated by the line connector.

Further, described with examples, the determination of which card of the given section is to be rendered can be conditional, based on state information recorded or otherwise developed during the production environment rendering. Additionally, examples line connectors can extend between cards, such as cards of a given section 430, 432, to define a sequence in which cards of a section are to be rendered. By way of example, within each section 430, 432, the sequence in which cards are rendered in the simulation environment can be determined by default to correspond to, for example, positioning of the cards along the horizontal axis, with a leftmost card being the first card of the section to be rendered. Absent other input or events, the next card to be rendered can correspond to the card that is positioned immediately adjacent and to the right of the rendered card. The implementation of such a default sequence rule can vary based on implementation.

FIG. 4B through FIG. 4F illustrate a simulated production-environment renderings of the design interface 410. The simulated production-renderings can be generated by simulation engine 200, operating as part of or in connection with the IGDS 100 being implemented in a simulation mode. In an example of FIG. 4B, an initial screen 452 of the interface (e.g., for mobile device app) is rendered, corresponding to the card 422 of section 430, where the section 430 includes cards 422 and 424 (based on user selection). The determination of the initial screen 452 can be based on a default rule or setting, user selection and/or user preference. For example, the section 430 may be selected for rendering in the simulated production-environment, based on user input or designation, and the selection of the card 422 as the initial card being rendered may be by way of a left-to-right default rule.

FIG. 4C illustrates that by default, card 424 of section 430 is rendered next as screen 454. Upon generating the simulated production-environment rendering of each card 422, 424, the simulation engine 200 records state information, reflecting that the card 424 was most recently rendered. In examples, the state information can maintain additional information, such as, for example, identifying each card that was rendered, the relative timing or sequence when each card was rendered, and/or a duration in which each card of a section was rendered during a simulation interval.

Following the screen 454, the simulation engine 200 can detect an event that is defined by the line connector 442. For example, the event may correspond to a user interacting with a design element which is the source of the line connector 442. As the line connector 442 terminates at the section 432, the simulation engine 200 may utilize state information associated with the section 432 to determine which of the cards 426, 428 of the section 432 to render next during the simulation. At the beginning of the simulation, none of the cards 426, 428 of the section 432 may have been rendered. Accordingly, in FIG. 4D, the simulation engine 200 renders the card 426 as the next screen 456, based on a default sequence rule (e.g., most far left card of a section is rendered first, followed by next card immediately adjacent to the right, etc.). Similarly, in response to a designated event (e.g., user interaction with tab, passage of time), in FIG. 4E, the default sequencing rule is used to select card 428 next as screen 458. Then, in response to an event specified by line connector 444 (e.g., user interaction with “Home” design element), the simulation engine 200 determines the next panel to display as screen 460. The line connector 444 terminates at the section 430. As described with examples, the simulation engine 200 utilizes state information associated with the section 430 to determine which of the cards 422, 424 of the section 430 to render as the display screen. With reference to FIG. 4F, in the current example, the state information reflects that the card 424 was most recently rendered. Based on the state information, the card 424 is used to render the screen 460.

Among other benefits and advantages, examples as described eliminate conventional practices where transitions between cards (for production-environment simulations) utilized line connectors between individual cards. Under such conventional approaches, the use of line connectors could clutter the view and complicate a user's understanding of the implemented flow between the various panels of a design interface. In collaborative environments, newly created flows by one user would also become difficult to detect or incorporate by other users. By contrast, examples as described enable the design user to terminate line connectors that signify card transitions for a given flow with a section of a target card. Further, by utilizing state information to determine which card of a section to render, examples prevent an unwanted outcome where the flow returns to the initial card (by default sequencing rule) of the section. This allows the design user to better visualize the flow of a design interface or presentation.

Network Computer System

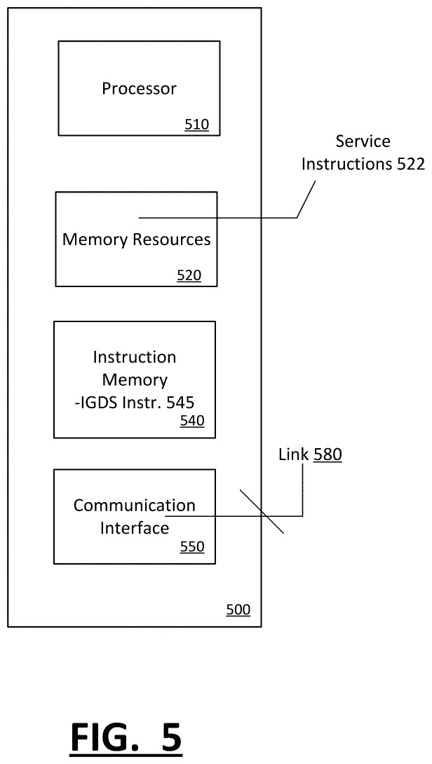

FIG. 5 illustrates a computer system on which one or more embodiments can be implemented. A computer system 500 can be implemented on, for example, a server or combination of servers. For example, the computer system 500 may be implemented as the network computing system 150 of FIG. 1A through FIG. 1C. Further, in some examples, the computer system 500 can provide instructions to the user device to enable the user device to implement functionality of the IGDS 100. Further, the computer system 500 can provide instructions to a user device, or otherwise perform operations to implement an example method (or steps therein) such as described with FIG. 3A and FIG. 3B.

In one implementation, the computer system 500 includes processing resources 510, memory resources 520 (e.g., read-only memory (ROM) or random-access memory (RAM)), one or more instruction memory resources 540, and a communication interface 550. The computer system 500 includes at least one processor 510 for processing information stored with the memory resources 520, such as provided by a random-access memory (RAM) or other dynamic storage device, for storing information and instructions which are executable by the processor 510. The memory resources 520 may also be used to store temporary variables or other intermediate information during execution of instructions to be executed by the processor 510.

The communication interface 550 enables the computer system 500 to communicate with one or more user computing devices, over one or more networks (e.g., cellular network) through use of the network link 580 (wireless or a wire). Using the network link 580, the computer system 500 can communicate with one or more computing devices, specialized devices and modules, and/or one or more servers.

In examples, the processor 510 may execute service instructions 522, stored with the memory resources 520, in order to enable the network computing system to implement the network service 172 and operate as the network computing system 170 in examples such as described with FIG. 1A through FIG. 1C.

The computer system 500 may also include additional memory resources (“instruction memory 540”) for storing executable instruction sets (“IGDS instructions 545”) which are embedded with web-pages and other web resources, to enable user computing devices to implement functionality such as described with the IGDS 100.

As such, examples described herein are related to the use of the computer system 500 for implementing the techniques described herein. According to an aspect, techniques are performed by the computer system 500 in response to the processor 510 executing one or more sequences of one or more instructions contained in the memory 520. Such instructions may be read into the memory 520 from another machine-readable medium. Execution of the sequences of instructions contained in the memory 520 causes the processor 510 to perform the process steps described herein. In alternative implementations, hard-wired circuitry may be used in place of or in combination with software instructions to implement examples described herein. Thus, the examples described are not limited to any specific combination of hardware circuitry and software.

User Computing Device

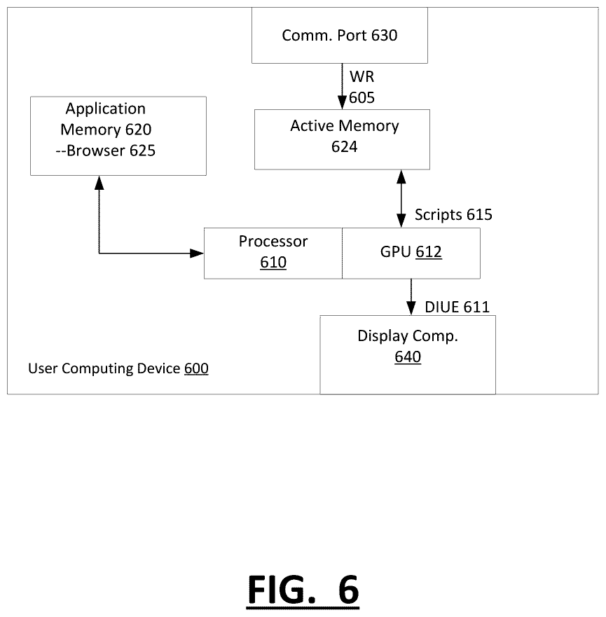

FIG. 6 illustrates a user computing device for use with one or more examples, as described. In examples, a user computing device 600 can correspond to, for example, a work station, a desktop computer, a laptop or other computer system having graphics processing capabilities that are suitable for enabling renderings of design interfaces and graphic design work. In variations, the user computing device 600 can correspond to a mobile computing device, such as a smartphone, tablet computer, laptop computer, VR or AR headset device, and the like.

In examples, the computing device 600 includes a central or main processor 610, a graphics processing unit 612, memory resources 620, and one or more communication ports 630. The computing device 600 can use the main processor 610 and the memory resources 620 to store and launch a browser 625 or other web-based application. A user can operate the browser 625 to access a network site of the network service 152, using the communication port 630, where one or more web pages or other resources 605 for the network service 152 (see FIG. 1A through FIG. 1C) can be downloaded. The web resources 605 can be stored in the active memory 624 (cache).

As described by various examples, the processor 610 can detect and execute scripts and other logic which are embedded in the web resource in order to implement the IGDS 100 (see FIG. 1A through FIG. 1C). Further, the processor 610 can execute scripts or instructions to perform an example method such as described with an example of FIG. 3. In some of the examples, some of the scripts 615 which are embedded with the web resources 605 can include GPU accelerated logic that is executed directly by the GPU 612. The main processor 610 and the GPU can combine to render a design interface under edit (“DUE 611”) on a display component 640. The rendered design interface can include web content from the browser 625, as well as design interface content and functional elements generated by scripts and other logic embedded with the web resource 605. By including scripts 615 that are directly executable on the GPU 612, the logic embedded with the web resource 615 can better execute the IGDS 100, as described with various examples.

### CONCLUSION

Although examples are described in detail herein with reference to the accompanying drawings, it is to be understood that the concepts are not limited to those precise examples. Accordingly, it is intended that the scope of the concepts be defined by the following claims and their equivalents. Furthermore, it is contemplated that a particular feature described either individually or as part of an example can be combined with other individually described features, or parts of other examples, even if the other features and examples make no mentioned of the particular feature. Thus, the absence of describing combinations should not preclude having rights to such combinations.

What is claimed is:

1. A computer system comprising:
one or more processors;
a memory to store a set of instructions;
wherein the one or more processors execute instructions stored in the memory to perform operations that include:
enabling a user to specify a plurality of cards that comprise a design interface or presentation, each of the plurality of cards being renderable in a simulation or production environment separate from other cards of the plurality of cards;
enabling a user to specify one or more sections, each section including a grouping of multiple cards of the plurality of cards;
enabling a user to specify multiple flow connections, the multiple flow connections including at least a first flow connection from one of the plurality of cards to a first section of the one or more sections, the one of the plurality of cards of the first flow connection not being part of the first section; and
during a simulation rendering of the design interface or presentation, rendering cards of the plurality of cards in a sequence that is based at least in part on one or more of the flow connections, including at least the first flow connection.

2. The computer system of claim 1, wherein rendering cards of the plurality of cards during the simulation rendering includes:
determining state information for the first section; and
selecting one of the cards of the first section to render based on the state information.

3. The computer system of claim 2, wherein determining state information for the first section includes identifying a most recent card of the section that was rendered during the simulation rendering.

4. The computer system of claim 3, wherein rendering cards of the plurality of cards in the sequence includes rendering at least one card based on the state information.

5. The computer system of claim 2, wherein the state information identifies a condition for selecting which of the multiple flow connections are to be used to determine a next card to render with the simulation rendering.

6. The computer system of claim 5, wherein the operations further comprise updating the state information based on the next card rendered during the simulation rendering.

7. The computer system of claim 1, wherein each of the multiple flow connections are specified as a corresponding graphic element that is rendered on a canvas of the design interface or presentation during a design mode.

8. A computer implemented method comprising:
enabling a user to specify a plurality of cards that comprise a design interface or presentation, each of the plurality of cards being renderable in a simulation or production environment separate from other cards of the plurality of cards;
enabling a user to specify one or more sections, each section including a grouping of multiple cards of the plurality of cards;
enabling a user to specify multiple flow connections, the multiple flow connections including at least a first flow connection from one of the plurality of cards to a first section of the one or more sections, the one of the plurality of cards of the first flow connection not being part of the first section; and
during a simulation rendering of the design interface or presentation, rendering cards of the plurality of cards in a sequence that is based at least in part on one or more of the flow connections, including at least the first flow connection.

9. The method of claim 8, wherein rendering cards of the plurality of cards during the simulation rendering includes:
determining state information for the first section; and
selecting one of the cards of the first section to render based on the state information.

10. The method of claim 9, wherein determining state information for the first section includes identifying a most recent card of the section that was rendered during the simulation rendering.

11. The method of claim 10, wherein rendering cards of the plurality of cards in the sequence includes rendering at least one card based on the state information.

12. The method of claim 9, wherein the state information identifies a condition for selecting which of the multiple flow connections are to be used to determine a next card to render with the simulation rendering.

13. The method of claim 12, further comprising updating the state information based on the next card rendered during the simulation rendering.

14. The method of claim 8, wherein each of the multiple flow connections are specified as a corresponding graphic element that is rendered on a canvas of the design interface or presentation during a design mode.

15. A non-transitory computer-readable medium that stores instructions, which when executed by one or more processors of a computer system, cause the computer system to perform operations that comprise:
enabling a user to specify a plurality of cards that comprise a design interface or presentation, each of the plurality of cards being renderable in a simulation or production environment separate from other cards of the plurality of cards;
enabling a user to specify one or more sections, each section including a grouping of multiple cards of the plurality of cards;
enabling a user to specify multiple flow connections, the multiple flow connections including at least a first flow connection from one of the plurality of cards to a first section of the one or more sections, the one of the plurality of cards of the first flow connection not being part of the first section; and
during a simulation rendering of the design interface or presentation, rendering cards of the plurality of cards in a sequence that is based at least in part on one or more of the flow connections, including at least the first flow connection.

16. The non-transitory computer-readable medium of claim 15, wherein rendering cards of the plurality of cards during the simulation rendering includes:
determining state information for the first section; and
selecting one of the cards of the first section to render based on the state information.

17. The non-transitory computer-readable medium of claim 16, wherein determining state information for the first section includes identifying a most recent card of the section that was rendered during the simulation rendering.

18. The non-transitory computer-readable medium of claim 17, wherein rendering cards of the plurality of cards in the sequence includes rendering at least one card based on the state information.

19. The non-transitory computer-readable medium of claim 17, wherein the state information identifies a condition for selecting which of the multiple flow connections are to be used to determine a next card to render with the simulation rendering.

20. The non-transitory computer-readable medium of claim 19, wherein the operations further comprise updating the state information based on the next card rendered during the simulation rendering.
